(19) United States
(12) Patent Application Publication
(10) Pub. No.: US 2025/0318315 A1
(43) Pub. Date: Oct. 9, 2025

(54) MONOLAYERS FOR RANDOM HOLE FORMATION FOR PASSIVATION AND TRANSPORT IN SILICON DEVICES

(71) Applicant: Alliance for Sustainable Energy, LLC, Golden, CO (US)

(72) Inventors: William Michael NEMETH, Wheat Ridge, CO (US); David Levi YOUNG, Golden, CO (US); Pauls STRADINS, Golden, CO (US)

(21) Appl. No.: 19/169,633

(22) Filed: Apr. 3, 2025

Related U.S. Application Data
(60) Provisional application No. 63/574,008, filed on Apr. 3, 2024.

(51) Int. Cl. H10F 77/20; H10F 71/00; H10F 77/30; H10F 77/70

(52) U.S. Cl. CPC H10F 77/211; H10F 71/129; H10F 77/311; H10F 77/703

(57) ABSTRACT

The present disclosure relates to a device that includes a silicon layer, a dielectric layer having a thickness, a self-assembled monolayer (SAM) having a thickness, and a layer constructed of a semiconductor, where the dielectric layer is positioned between the SAM and the silicon layer and the SAM is positioned between the layer comprising the semiconductor and the silicon layer. The SAM includes a plurality of imperfections that pass through the thickness of the SAM, the dielectric layer includes a plurality of holes that pass through at least a portion of the thickness of the dielectric layer, and the imperfections and the holes are substantially aligned to form a plurality of continuous channels and at least a portion of the channels are at least partially filled with the semiconductor, such that the channels are capable of charge transport between the silicon layer and the layer comprising the semiconductor.

### CROSS-REFERENCE TO RELATED APPLICATIONS

This application claims the benefit of U.S. Provisional Patent Application No. 63/574,008 filed Apr. 3, 2024, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

Passivated contacts are being implemented into silicon (c-Si) solar cell production due to the striking improvement in cell efficiencies reaching over 26%. However, current methods for manufacturing such contacts are too complex for full-scale industrial applications. Thus, there remains a need for improved methods, that are simpler, require less intensive process conditions, and that are more economically feasible for large scale implementation.

### SUMMARY

An aspect of the present disclosure is a device that includes a silicon layer, a dielectric layer having a thickness, a self-assembled monolayer (SAM) having a thickness, and a layer constructed of a semiconductor, where the dielectric layer is positioned between the SAM and the silicon layer and the SAM is positioned between the layer comprising the semiconductor and the silicon layer. Further, the SAM includes a plurality of imperfections that pass through the thickness of the SAM, the dielectric layer includes a plurality of holes that pass through at least a portion of the thickness of the dielectric layer, and the imperfections and the holes are substantially aligned to form a plurality of continuous channels. In addition, at least a portion of the channels are at least partially filled with the semiconductor, such that the channels are capable of charge transport between the silicon layer and the layer comprising the semiconductor.

In some embodiments of the present disclosure, the imperfections may include at least one of a hole, a crack, an area not covered by the SAM, or a combination thereof. In some embodiments of the present disclosure, the SAM may be derived from a plurality of SAM precursors molecules. In some embodiments of the present disclosure, the molecules may include polyethylenimine (PEI). In some embodiments of the present disclosure, the molecule may include silicon. In some embodiments of the present disclosure, the molecule may include at least one of hexamethyldisilazane (HMDS), trichlorooctadecylsilane, ((3-aminopropyl)triethoxysilane) (APTES), dimethylaminotrimethylsilane, N-methyl-aza-2,2,4-trimethylsilacyclopentane, a cyclic azosilanes, fluoro-alkyl silanes, or a combination thereof.

In some embodiments of the present disclosure, the dielectric layer may include at least one of a metal oxide, a metal carbide, a metal nitride, or a combination thereof. In some embodiments of the present disclosure, the metal of the metal oxide may include at least one of silicon, aluminum, hafnium, tin, zirconium, titanium, zinc, or a combination thereof. In some embodiments of the present disclosure, the dielectric layer may include at least one of SiO_{z}, SiₓN_{y}, or a combination thereof, wherein 0.1≤z≤2.5, 0≤x≤2, and 0≤y≤2. In some embodiments of the present disclosure, the dielectric layer may have a thickness between 0.1 nm and 200 nm.

In some embodiments of the present disclosure, a first portion of the plurality of holes may terminate with a layer of the dielectric layer remaining in contact with the silicon layer. In some embodiments of the present disclosure, the layer of the dielectric layer remaining may have a thickness between 0.8 nm and 2.0 nm, or between 1.1 nm and 1.5 nm, or between 1.3 nm and 1.5 nm. In some embodiments of the present disclosure, a first portion of the plurality of holes may penetrate the entire thickness of the dielectric layer. In some embodiments of the present disclosure, a second portion of the plurality of holes may penetrate into the silicon layer. In some embodiments of the present disclosure, the plurality of holes may have an average diameter between 1 nm and 1000 nm. In some embodiments of the present disclosure, the plurality of channels may be present at a concentration between 1×10⁴ holes/cm² and 1×10¹⁰ holes/cm².

In some embodiments of the present disclosure, the semiconductor layer may include at least one of silicon, titanium oxide, zinc oxide, tin oxide, indium oxide, indium-tin oxide, germanium, arsenic, antimony, aluminum, titanium, indium, molybdenum oxide, carbon, 2,2′,7,7′-tetrakis[N,N-di(4-methoxyphenyl)amino]-9,9′-spirobifluorene (spiro-OMeTAD), polymer poly[bis(4-phenyl)(2,4,6-trimethylphenyl)amine] (PTAA), CdTe, GaAs, AlSb, ZnTe, CdSe, or a combination thereof. In some embodiments of the present disclosure, the semiconductor layer may include crystalline silicon. In some embodiments of the present disclosure, the crystalline silicon may be polycrystalline silicon.

An aspect of the present disclosure is a method comprising a first depositing of a self-assembled monolayer (SAM) onto a dielectric layer and contacting the SAM with an etchant, where the dielectric layer is a conformal layer covering a first silicon layer. Further, after the first depositing, the SAM includes a first portion that prevents the dielectric layer from being contacted by the etchant and a second portion that allows the dielectric layer to be contacted by the etchant, and during the contacting, the etchant removes at least a portion of the dielectric layer underlying the second portion, resulting in the forming of a plurality of holes that penetrate into the dielectric layer.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1 illustrates a method for making a device, according to some embodiments of the present disclosure.

FIG. 2 illustrates a device resulting from a method like that illustrated in FIG. 1, according to some embodiments of the present disclosure.

FIG. 3 illustrates performance metrics (V_{oc}, J_{sc}, fill factors (FFs), and efficiencies) of cells manufactured using methods described herein, according to some embodiments of the present disclosure.

FIG. 4 illustrates Panel a) a schematic of a transfer length method (TLM) pattern on devices made using methods described herein that include a n/poly symmetric (i.e., double-side) structure and Panel b) the resulting photoluminescence images taken through the wafer of saw damage removed (SDR) and textured (TXT) TLM samples prior to etching the semiconducting material between the pads (pad isolation), according to some embodiments of the present disclosure.

FIG. 5 illustrates a schematic of a double-side poly-Si passivated contact solar cell that may be manufactured using the methods described herein, according to some embodiments of the present disclosure.

FIG. 6 illustrates a SAM functionalization mechanism showing the gradual increase in the coverage of a dielectric layer by a SAM and the corresponding gradual decrease in uncovered portions (i.e., imperfections) of the dielectric layer, according to some embodiments of the present disclosure.

FIG. 7 illustrates HMDS-derived SAM on a dielectric on c-Si Panel a) AFM pre-HF SiNₓ, Panel b) atomic force microscopy (AFM) images of post-HF SiNₓ, Panel c) scanning electron microscopy (SEM) images of pre-HF SiO₂, Panel d) SEM post-HF SiO₂ with Ag plating, according to some embodiments of the present disclosure.

FIG. 8 illustrates Panel a) a plot of water contact angle versus HMDS vapor exposure time of SiO₂ (circles) and SiNₓ (squares) on Si with and without UV-O₃ pretreatment and Panel b) a plot of aggregate thickness of bare SiO₂ (open markers) and HMDS coated SiO₂ (filled markers) versus 0.1 vol % HF time, according to some embodiments of the present disclosure.

FIG. 9 illustrates Panel a) an AFM image of holes in a 2 nm thick SiO₂ dielectric layer, Panel b) a schematic of HF etching characteristics through a SAM having imperfections creating SiO₂ holes, Panel c) an AFM image of a hole in 10 nm thick SiNₓ dielectric layer, and Panel d) an AFM image of longer etch time for forming holes in a SiNₓ dielectric layer, according to some embodiments of the present disclosure.

FIG. 10 illustrates Panel a) an EBIC image of n/poly-Si on KOH etched p-Cz Si (p-doped silicon by the Czochralski process), Panel b) an SEM image of textured c-Si after TMAH removal of n/poly-Si, Panel c) Ag decorated holes in SiO₂ on textured c-Si, and Panel d) a TEM image of Ag nanoparticle on a pinhole, according to some embodiments of the present disclosure. Circles identify examples of pinholes as a guide to the eye.

FIG. 11 illustrates cell efficiency dependence on HMDS functionalization and subsequent 0.1% HF etch time, according to some embodiments of the present disclosure.

FIG. 12 illustrates Panel a) a schematic of cell, and subsequent HF treatment time effects on cells with and without an HMDS SAM layer, Panel b) Fill Factor (FF), Panel c) V_{oc}, and Panel d) Efficiency under AM1.5 light, according to some embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### REFERENCE NUMERALS

100 . . . method
102 . . . starting wafer
104 . . . self-assembled monolayer (SAM) precursor
110 . . . first depositing
112 . . . first device
114 . . . etchant
120 . . . contacting
122 . . . second device
124 . . . silicon precursor
130 . . . second depositing
132 . . . third device
140 . . . annealing
142 . . . final device
200 . . . dielectric layer
210 . . . first silicon layer
220 . . . self-assembled monolayer (SAM)
230 . . . imperfection
235 . . . hole
240 . . . second semiconductor layer
242 . . . second semiconductor penetration
250 . . . annealed semiconductor layer
400 . . . metal contact

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The present disclosure relates to the use of self-assembled monolayers (SAM), specifically the depositing of a SAM (via liquid and/or gas phase deposition methods) onto the surface of a dielectric layer covering an underlying semiconductor layer (such as silicon). SAMs are synthesized using SAM-precursor molecules, for example hexamethyldisilazane (HMDS). The dielectric layer is positioned between the SAM and the semiconductor layer. As shown herein, the attachment and percent coverage of a SAM on a dielectric layer may be time dependent, such that after a specific time, the coverage of the dielectric layer by the SAM may visually appear to be complete, e.g., appearing to be conformal. However, by utilizing the time dependency of SAM coverage of a dielectric layer and other process variables, incomplete SAM coverage may be established, leaving some areas of a dielectric's surface uncovered (e.g., as holes, cracks, etc.) and susceptible to the use of a chemical etchant (e.g., HF). As a result, these areas of incomplete SAM coverage, when contacted with a chemical etchant, may result in the preferential etching of the underlying dielectric layer and the forming of holes and/or channels passing through the thickness of the dielectric layer, or at least passing through enough of the dielectric layer's thickness to render any remaining dielectric layer capable of charge tunneling. These holes and/or channels through the dielectric layer may thereby expose the underlying semiconductor layer, whereas the portions of dielectric layer covered by the SAM may remain essentially hole-free. This process of hole formation (and/or partial hole formation) through a dielectric layer may be at least partially controlled by selecting SAMs that are more chemically resistant to the chosen etchant than the underlying dielectric layer.

The etching and resultant formation of holes through a dielectric layer may provide a “templated structure”, which allows the subsequent deposition of a carrier selective material (e.g., a charge-doped amorphous silicon) on top of the dielectric layer (and any remaining SAM). The deposited carrier selective material may then penetrate into the dielectric layer, passing through at least a portion of its thickness by filling the holes, resulting in the direct contact of carrier selective material with the underlying semiconductor material and/or a separation of the carrier selective material and the underlying semiconductor material, defined by a remaining dielectric layer that is sufficiently thin to allow charge tunneling to occur.

In some embodiments of the present disclosure, two or more SAM precursor molecules may be mixed and deposited onto the surface of a dielectric layer. Subsequent contacting of the resultant SAM with the chemical etchant may preferentially etch in the specific locations of one SAM, while other surfaces, covered by different SAMs having a higher resistances to the etchant, may slow or eliminate hole formation in their corresponding underlying dielectric layer. As a result, the use of two or more SAM precursor molecules may result in a templated structure having a plurality of holes that pass through the thickness of the dielectric layer and/or substantially through its thickness, thereby exposing the underlying semiconductor layer and/or enabling charge tunneling to the underlying semiconductor layer, to just those locations where holes and/or partial holes were formed. In addition, a surface treatment of a dielectric layer may be performed to influence the attachment and coverage of the subsequently deposited SAM, thereby providing an additional process variable that may be adjusted to control hole diameters, dielectric layer thickness penetration, and surface concentrations. Examples of surface treatments include UV/ozone treatment, oxidizing acid treatments (e.g., as with nitric acid), and/or controlled surface contamination with hydrocarbons.

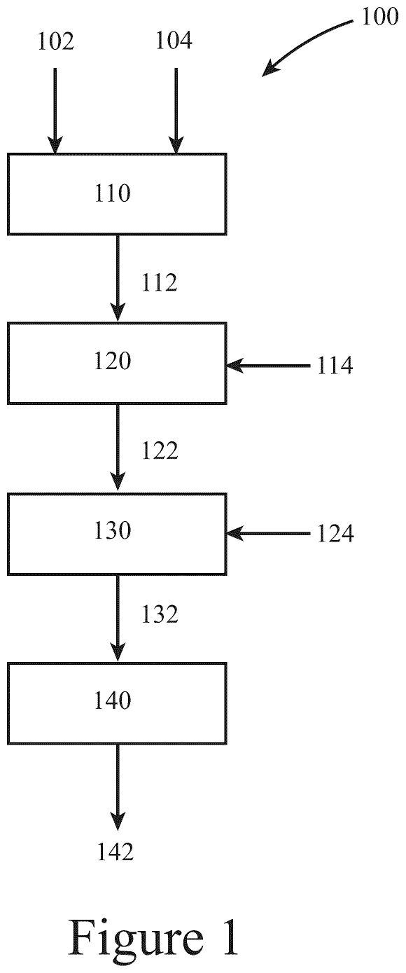

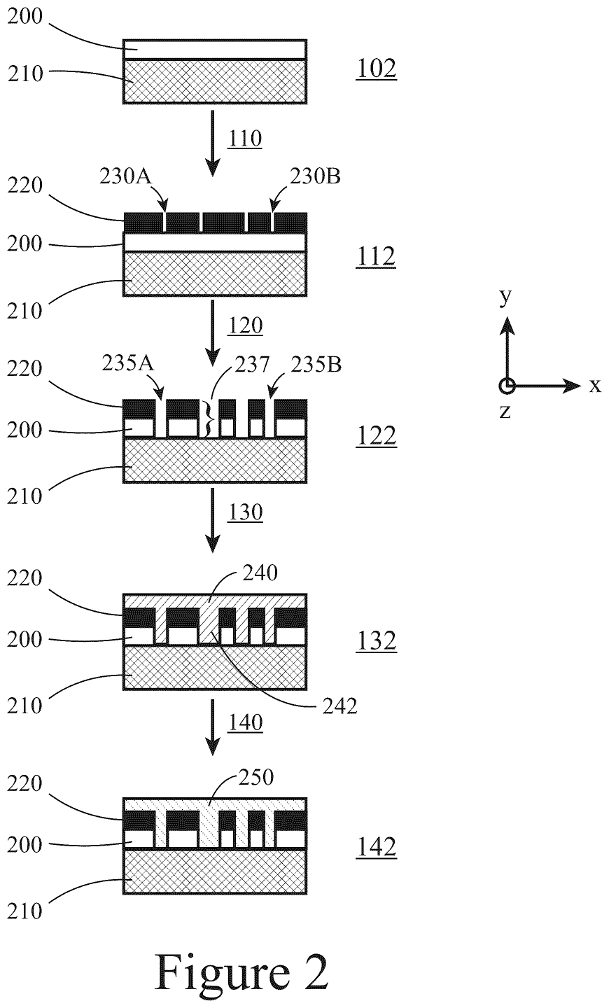

FIG. 1 illustrates a method 100 for manufacturing a device 142, according to some embodiments of the present disclosure. Such a device 142 may be based on a silicon wafer and may include, as a result of use of the method 100, passivated contacts having a dielectric layer with a plurality of holes passing through and/or substantially through the dielectric layer, thereby exposing the underlying silicon wafer directly to a second semiconductor and/or enabling charge tunneling, as described above. FIG. 2 illustrates a schematic of the various intermediate devices resulting from the various steps of the method of FIG. 1, concluding with the manufacture of the final device 142. The method 100 illustrated in FIG. 1 and the resultant intermediate devices and the final device 142 illustrated in FIG. 2 are provided as examples and are not necessarily limiting. Further, a device 142 may in some cases be the “final” product resulting from a method or, in some embodiments of the present disclosure, a final device 142 may be an intermediate device that is processed further in subsequent steps, e.g., the depositing of additional device layers; e.g., contacts, etc.

Note that the shapes/profiles of the holes 235 and silicon penetrations 242 shown in FIG. 2 are shown for illustrative purposes and are not intended to be limiting. In some embodiments of the present disclosure, the shapes/profiles of the holes 235 and resultant silicon penetrations 242 may be other than square-shaped and/or rectangular-shaped; e.g., round profiles, elliptical profiles, and/or irregular shapes/profiles. In addition, the holes 235 illustrated in FIG. 2 are shown as completely penetrating the thickness of the dielectric layer 200. However, as discussed previously, some holes 235 resulting from chemical etching may not penetrate the complete thickness of a dielectric layer 200 and a thin layer of dielectric layer may remain in contact with the first silicon layer 210, that is sufficiently thin to allow charge tunneling through the remaining dielectric layer to occur. In some embodiments of the present disclosure, such a thin remaining layer of dielectric layer may have a thickness in the y-axis direction between 0.8 nm and 2.0 nm, or between 1.1 nm and 1.5 nm, or between 1.3 nm and 1.5 nm.

As shown in FIGS. 1 and 2, a method 100 may begin with a first depositing 110 of a self-assembled monolayer (SAM) 220 onto a starting wafer 102 having a dielectric layer 200 positioned on a first silicon layer 210, resulting in the forming of a first device 112. A SAM 220 may be deposited by a liquid-phase and/or vapor-phase application of a SAM-precursor molecule to the surface of dielectric layer 200. Once deposited, a SAM 220 may appear, for example by optical methods, to be conformal. However, the first depositing 110 may result in a SAM 220 having imperfections 230 (two called out as reference numerals 230A and 230B), such as cracks and/or holes or simply areas on the surface of the dielectric layer 200 that are not covered by the SAM 220. Imperfections 230 in a SAM 220 may be visualized using atomic force microscopy.

These imperfections 230 may provide pathways for a chemical etchant to penetrate through the otherwise protective SAM 220 to access and etch the underlying dielectric layer 200. Such etching may be achieved by contacting 120 the first device 112 with an etchant 114, e.g., a liquid phase and/or vapor phase application of the etchant to the surface of the SAM 220, resulting in the forming of a second device 122, characterized by the formation of a plurality of holes 235 (two called out as reference numerals 235A and 235B) where, in some embodiments of the present disclosure, at least a portion of the holes 235 pass through the entire thickness (in the y-axis direction) of the dielectric layer 200. The holes 235 resulting from the contacting 120 of the first device 112 with an etchant 140 may, therefore, result in open paths, or channels 237, from the external environment, through the thickness of the SAM 220 and the thickness and/or partial thickness of the dielectric layer 200 (in the y-axis direction) to the underlying surface and/or nearly to the surface (in a plane parallel to the xz-plane) of the first silicon layer 210. Thus, the alignment of imperfections 230 and holes 235 may form continuous channels 237 from the external environment to the surface of the first silicon layer 210 and/or to near the surface of the first silicon layer 210. In some embodiments of the present disclosure, at least a portion of the holes 235 resulting from the contacting 120 may not penetrate the full thickness of the dielectric layer 200 but may penetrate enough to enable charge tunneling through the remaining thickness of dielectric layer 200. Note that FIG. 2 is not drawn to scale.

These paths, i.e., holes 235, combined with the dielectric layer 200, advantageously allow for a second depositing 130 of a second semiconductor layer 240 (e.g., amorphous silicon) onto the second device 122, resulting in a third device 132, where some of the material of the second semiconductor layer 240 penetrates into at least a portion of the holes 235, to pass through the thickness of the SAM 220 and the thickness and/or partial thickness of the dielectric layer 200, to physically contact a portion of the surface of the underlying first silicon layer 210 (and/or enabling charge tunneling to occur). These semiconductor penetrations 242, therefore, provide pathways for charge transport to occur between the first silicon layer 210 and the second semiconductor layer 240. Thus, by the careful selection of SAM precursors 104, SAM 220 coverage over a dielectric layer 200, dielectric layer 200 thickness, etchant 114, and various process conditions, the number of holes 235, hole size distribution, hole penetration through the dielectric layer 200, and hole density may be independently tuned to achieve a desired balance of passivation and charge transport. Further, the method 100 described herein is potentially simpler and may use lower processing temperatures (e.g., between 0° C. and 100° C.) than incumbent technologies (e.g., the POLO process by the Institute for Solar Energy Research in Hamelin, Germany). Unlike incumbent technologies, the methods described herein may be used to produce holes in dielectric layers and may be used to pattern to specific desired target areas on a device, such as underneath a solar cell's metal gridlines, and/or only under an interdigitated solar cell's back contacts.

Referring again to FIG. 2, in some embodiments of the present disclosure, a second semiconductor layer 240 may be constructed of substantially amorphous silicon. To convert the amorphous silicon to crystalline silicon, a method 100 (referring to FIG. 1) may continue with the annealing 140 (e.g., heating to an elevated temperature) of a third device 132, such that a final device 142 is formed, with the second semiconductor layer 240, in the form of amorphous silicon, being converted to a crystalline silicon layer, referred to herein as an annealed semiconductor layer 250. However, in some embodiments of the present disclosure, a method 100 may not include an annealing 140 step, and a third device 132 may be the “final” targeted device. In some embodiments of the present disclosure, a method 100 may proceed with one or more additional steps (not shown in FIG. 1), for example, the depositing of at least one contact layer constructed of a conductive metal such as aluminum, copper, nickel, gold, and/or silver.

In some embodiments of the present disclosure, a second semiconductor layer 240 may be made of some other semiconductor material, other than or in addition to silicon, where the semiconductor material has the appropriate band alignment. In some embodiments of the present disclosure, a second semiconductor layer 240 and/or an annealed semiconductor layer 250 may be constructed of at least one of titanium oxide, zinc oxide, tin oxide, indium oxide, indium-tin oxide, germanium, arsenic, antimony, aluminum, titanium, indium, molybdenum oxide, carbon, 2,2′,7,7′-tetrakis[N,N-di(4-methoxyphenyl)amino]-9,9′-spirobifluorene (spiro-OMeTAD), polymer poly[bis(4-phenyl)(2,4,6-trimethylphenyl)amine] (PTAA), CdTe, GaAs, AlSb, ZnTe, and/or CdSe. In some embodiments of the present disclosure, a semiconductor selected for a second semiconductor layer 240 may have a band alignment that is between greater than 0 eV and 0.25 eV for one of the bands (valence or conduction band edge versus that of silicon). For the examples of metals listed above, the band alignment is replaced with aligning the metal's Fermi level (work function) to the conduction band edge or valence band edge of silicon; in some embodiments of the present disclosure, the Fermi level of a metal selected for a second semiconductor layer 240 may be aligned with the silicon conduction or valance band between 0 eV and 0.25 eV.

Referring again to FIGS. 1 and 2, in some embodiments of the present disclosure, a surface of a first silicon layer 210 of a starting wafer 102 may be textured (e.g., pyramidal) or have an irregular surface, for example, a surface resulting from cutting a starting ingot of semiconductor material using a saw and/or etched to removed saw cutting defects. In some embodiments of the present disclosure, a first silicon layer 210 of a starting wafer 102 may be constructed of crystalline silicon manufactured by the Czochralski process, with the starting wafer 102 having an as-cut surface in the (100) crystal orientation. In some embodiments of the present disclosure, a first silicon layer 210 may be amorphous or crystalline. In some embodiments of the present disclosure, a first silicon layer 210 may be doped, n-doped and/or p-doped. In some embodiments of the present disclosure, a first silicon layer 210 may be n-doped with phosphorus, antimony, arsenic, and/or nitrogen at a concentration between 10¹³ and 10¹⁷ cm⁻³, or p-doped with boron, gallium, indium, and/or aluminum at a concentration between 10¹⁴ and 10¹⁷ cm⁻³, with a thickness between 10 microns and 500 microns.

In some embodiments of the present disclosure, a dielectric layer 200 may be constructed of at least one of a metal oxide and/or a silicon nitride. The metal of a metal oxide used to construct a dielectric layer 200 may include at least one of silicon, aluminum, hafnium, indium, titanium, nickel, tin, and/or zinc. In some embodiments of the present disclosure, a dielectric layer 200 may be constructed of at least one of SiOₓ (where 0.5≤x≤2.5) and/or a SiₓN_{y}, where 0≤x≤3 and 0≤y≤4. In some embodiments of the present disclosure, a dielectric layer 200 may have a thickness between 0.1 nm and 200 nm or between 1.0 nm and 20 nm. In some embodiments of the present disclosure, a dielectric layer 200 of a starting wafer 102 may have the same surface shape/morphology as the first silicon layer 210 onto which it is deposited. Thus, a dielectric layer 200 may have a textured surface, for example, a pyramidal surface and/or a surface resembling the morphology of a saw-cut silicon ingot.

In some embodiments of the present disclosure, a surface (in a plane parallel to the xz-plane) of a dielectric layer 200 may be reacted with a SAM-forming molecule such that the reacting results in the forming of the SAM 220. In some embodiments of the present disclosure, a SAM 220 may have a thickness that is about equal to the diameter of the unreacted SAM-forming molecule, e.g., between 3 Å and 30 Å (i.e., SAM precursor 104). In some embodiments of the present disclosure, a SAM-forming molecule may be a silicon-containing molecule, for example hexamethyldisilazane (HMDS), a cyclic azosilane, and/or a fluoro-alkyl silane. In some embodiments of the present disclosure, a SAM resulting from one or more SAM-forming molecules may be crosslinked and/or uncrosslinked. Examples of SAM-forming molecules capable of crosslinking include APTES ((3-aminopropyl)triethoxysilane), which provides a silicon end-atom with hydroxl groups (—OH groups) after hydrolysis. These hydroxyl groups can then react with both hydroxl groups on the surface of the dielectric layer 200 and with the hydroxl groups of neighboring APTES molecules, thus forming a covalently bonded layer of SAM-forming layers, with crosslinking between neighboring SAM-forming molecules, resulting in a cross-linked SAM 220. Two reacting hydroxl groups of neighboring APTES molecules results in the formation of an oxygen-bridging bond (siloxane bond), forming water as a leaving molecule.

A SAM 220 may be deposited by a vapor phase method and/or a liquid phase method that applies a SAM-forming molecule to a surface of a dielectric layer 200. In some embodiments the present disclosure, a vapor phase deposition method for depositing a SAM 220 onto a dielectric layer 200 may be achieved using an enclosed vessel ambient vapor soak. An “ambient vapor soak” is performed by placing a starting wafer 102 and SAM-forming molecules in a sealed vessel, which is maintained at room temperature. The atmosphere inside the vessel then reaches an equilibrium saturation of SAM-forming molecules, some of which condense on the surface of the starting wafer 102, thus forming a SAM 220. In some embodiments the present disclosure, an enclosed vessel ambient vapor soak may be performed for a period of time between 1 minute and 24 hours. In some embodiments the present disclosure, an enclosed vessel ambient vapor soak may be performed at a temperature between 15° C. and 200° C. or between 25° C. and 100° C. In some embodiments the present disclosure, an enclosed vessel ambient vapor soak may be performed at a pressure between 0.5 atm-absolute and 2.0 atm-abs or between 0.9 atm-abs and 1.2 atm-abs.

Referring again to FIGS. 1 and 2, in some embodiments of the present disclosure, a first depositing 110 may result in a SAM 220 that includes a first portion that prevents the underlying dielectric layer 200 from being contacted by an etchant and a second portion that permits the underlying dielectric layer 200 to be contacted by the etchant. In some embodiments of the present disclosure, such a second portion may be the result of imperfections in the SAM 220. As a result, during the contacting 120, an etchant 114 may remove at least a portion of the dielectric layer 200 underlying the second portion, resulting in the forming of a plurality of holes that penetrate the dielectric layer 200, thereby exposing of the underlying first silicon layer 210. In some embodiments of the present disclosure, an etchant 114 may include an acid such as hydrofluoric acid (HF) and/or HNH₄F. HF may be provided to the surface of a SAM layer in a solution having an HF concentration between 0.01 wt % and 5 wt % or between 0.1 wt % and 2 wt %. In some embodiments of the present disclosure, contacting 120 may be performed at a temperature between 20° C. and 50° C. and for a period of time between 1 second and 60 minutes.

As described herein, contacting 120 a SAM 110 with an etchant 114 may convert a portion of the imperfections 230 originally present in the SAM 110 after a first depositing 110, to a plurality of holes 235, where at least a portion of the plurality of holes 235 pass through the entire thickness of the dielectric layer 235. In some embodiments of the present disclosure, holes 235 resulting from the contacting 120 may have an average diameter between 1 nm and 1000 nm or between 5 nm and 100 nm. In some embodiments of the present disclosure, a plurality of holes 235 may be present in a dielectric layer 200 at a concentration (i.e., areal density) between 1×10⁴ holes/cm² and 1×10¹⁰ holes/cm² or between 1×10⁵ holes/cm² and 1×10⁸ holes/cm². In some embodiments of the present disclosure, an average diameter and areal density of holes 235 passing through a dielectric layer 200 may be approximately the same before and after a second depositing 130 of a second silicon layer 240 onto a second device 122. In some embodiments of the present disclosure, after contacting 120 a first device 112 with an etchant may result in a percentage of holes completely penetrating the thickness of the dielectric layer 200 greater than 20%, greater than 30%, greater than 40%, greater than 50%, greater than 60%, greater than 70%, greater than 80%, greater than 90%, greater than 99%, or greater than 99.9%. In addition to forming and/or modifying holes 235, contacting 120 a SAM 110 with an etchant 114 may result in a second device 112 having a surface roughness between 0.1 nm and 100 nm or between 0.3 nm and 3 nm.

Referring again to FIGS. 1 and 2, in some embodiments of the present disclosure, after contacting 120 a first device 112 with an etchant 114, a method 100 may continue with a second depositing 130 of a second semiconductor layer 240 (e.g., amorphous silicon) onto the second device 122, resulting in the forming of a third device 132. In some embodiments of the present disclosure, a method for depositing a second semiconductor layer 240 may include plasma enhanced chemical vapor deposition (PECVD) for depositing doped amorphous silicon (a-Si:H) using silane (SiH₄) and a dopant precursor such as diborane and/or phosphine. To achieve this, PECVD may be performed at a temperature of between 100° C. and 450° C., a pressure between 0.4 Torr and 1.5 Torr, and a power of about 10 mW/cm² and 100 mW/cm² RF power. Other methods for depositing a second semiconductor layer 240, e.g., silicon, may include sputtering, low pressure chemical vapor deposition (LPCVD), physical vapor deposition (PVD), and/or metalorganic vapor deposition (MOCVD). In some embodiments of the present disclosure, a second silicon layer 250 may be constructed of amorphous silicon and/or polycrystalline silicon with a thickness between 5 nm and 300 nm or between 20 nm and 100 nm, doped either n-type of p-type, with dopant concentrations between 10¹⁵ cm⁻³ and 10²¹ cm⁻³ or between 10¹⁹ cm⁻³ and 3×10²⁰ cm⁻³.

In some embodiments of the present disclosure, after a second depositing 130 of a second semiconductor layer 240, a method 100 may proceed with an annealing 140 of at least the second semiconductor layer 240 or the entire third device 132. For example, a second semiconductor layer 240 of amorphous silicon layer may be converted by annealing 140 to a substantially polycrystalline silicon layer, referred to generally herein as an annealed semiconductor layer 250. In some embodiments of the present disclosure, annealing 140 may be performed by heating the second semiconductor layer 240 to a temperature between 600° C. and 1000° C. or between 800° C. and 950° C. and maintaining that temperature for a period of time between 5 minutes and 240 minutes or between 15 minutes and 60 minutes. In some embodiments of the present disclosure, annealing 140 may result in the transfer of a dopant from a second silicon layer 240 to a first silicon layer 210, where the transfer occurs through the plurality of penetrations 242 (i.e., through the semiconductor-filled holes). In some embodiments of the present disclosure, the atmosphere during annealing 140 may include at least one of air, nitrogen, and/or a noble gas.

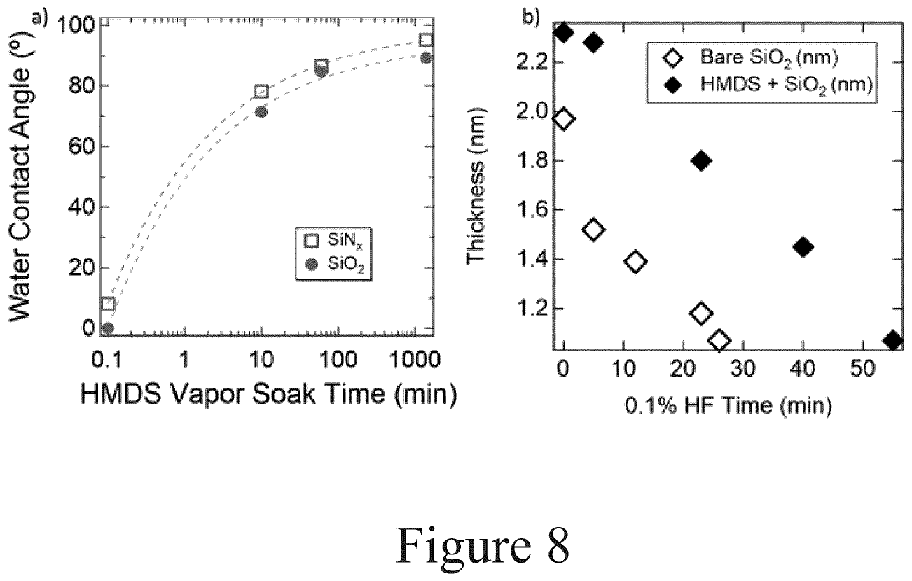

Initial experiments using the methods described above utilized water contact angle measurements (WCA) versus time to determine when conformal full area coverage of SAMs 220 was achieved on surfaces. This was shown, using HMDS, to be about 10 hours for full coverage on both an SiO₂ dielectric layer 200 and a c-Si (crystalline silicon) first silicon layer 210 (see FIG. 8). Next, the time that an HMDS-derived SAM 220 can physically withstand contact with dilute HF was determined. It was determined that an HMDS-derived SAM 220 can withstand contact with 2 vol % HF for approximately 10 seconds or for at least 60 minutes when contacted with 0.1% HF, thereby defining a contact time inversely proportional to HF concentration; a contact time between about 1 second and 1 hour for an HF concentration between 2 vol % and 0.1 vol % HF.

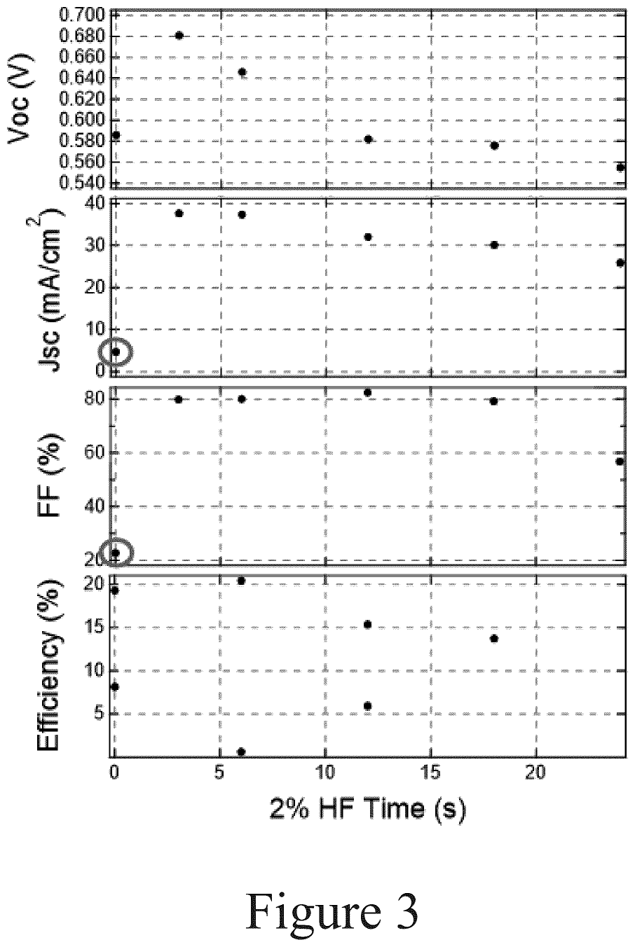

Initial tests using SAMs were completed using monolithic double-side devices, both sides having poly-Si passivated layers (annealed semiconductor layers 250), grown on textured c-Si layers (first silicon layers 210), and with ˜2.0 nm thick SiO₂ dielectric layers 200. After oxidation, the samples were functionalized in vapor HMDS for approximately 30 minutes (first depositing 110) to form SAMs 220, then contacted (i.e., etched) with a 2% HF aqueous solution (contacting 120) for different times, prior to completing the device (final device 142). The resulting devices performed relatively poorly as evidenced by low V_{oc}. Regardless, successful rectifying J-V (see FIG. 3) curves were measured as a function of HF etch time, where an efficiency of 20.4% was achieved after 6 seconds. In contrast, for a sample lacking the etching due to the HF contacting step, a very high resistance (circled in FIG. 3) was measured due to the presence of the unetched 2 nm thick SiO₂ dielectric layer. This confirmed the feasibility of using SAMs 220 to form “templates” for creating holes 235 passing through SiO₂ dielectric layers 200 and for the subsequent creation of silicon penetrations 242 to contact the underlying first silicon layer 210 (and/or creating penetrations that enable charge tunneling), enabling the creation of carrier selective contacts.

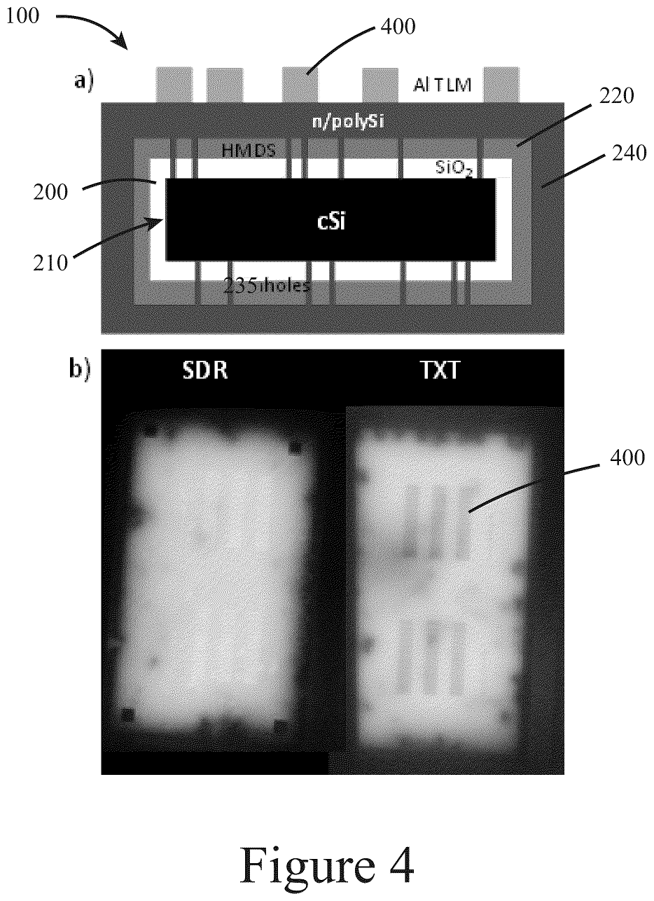

Studies continued with focus on symmetric n/poly-Si structures (n-doped polycrystalline structures) (see Panel a of FIG. 4) to remove complications from boron, since boron can cause performance degradation by boron diffusing into SiO₂ dielectric layers 200 with deleterious effects, as well as the formation of second phases in c-Si annealed semiconductor layers 250. Excellent passivation was achieved on both textured (TXT) (˜715 mViV_{oc}) and saw damage removed (SDR) (˜740 mViV_{oc}) surface morphologies for first silicon layers 210. Transport with TLM (transfer length method) measurements were then measured on these devices, before and after etching the materials between the metal contacts 400 to electrically isolate the metal contacts 400. Prior to isolation, photoluminescence images (see Panel b of FIG. 4) show excellent preservation of passivation under the metal contacts 400, albeit with some dark spots assigned to impurities introduced during the process of constructing the devices. The metal contacts 400 are visible as vertically aligned stripes. Metal-to-n/poly-Si contact resistivity is excellent (1-20 mΩ-cm²) for all samples prior to isolating the metal TLM contacts 400. Note that the metal contacts 400 are not included in an actual device and were added in the devices described herein to enable the TLM measurements. However, after isolation (after removing all layers above the first silicon layer 210, in all areas except below the metal contacts 400 using reactive-ion etching), very high resistances were measured on multiple samples which were not treated long enough to induce the formation of holes. Samples that resulted in low specific contact resistivities (30 mΩ-cm² for SDR and 2-5 mΩ-cm² for textured (TXT)) were subjected to longer HF contacting times during the hole formation process, validating the methods described herein. These pre-isolated TLM samples can be seen in Panel b of FIG. 4, where the metal contacts are visible but do not degrade passivation significantly.

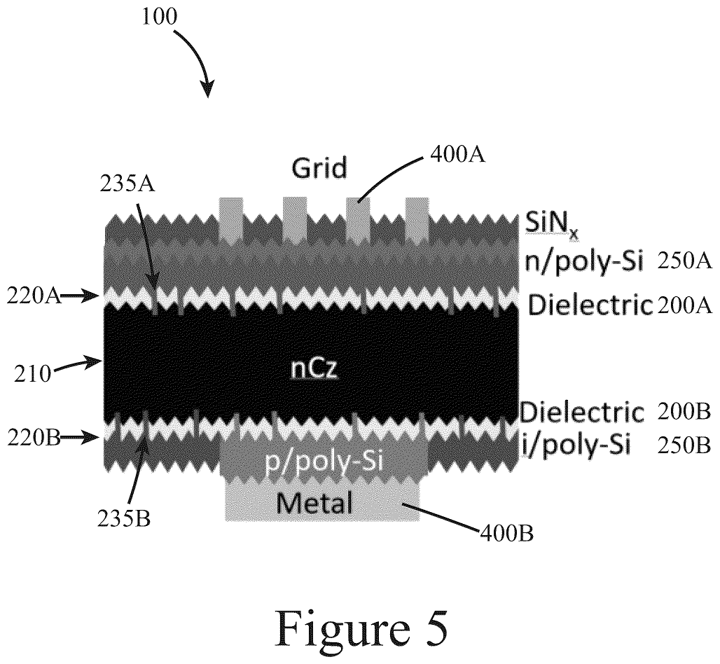

FIG. 5 illustrates a schematic of another device that may be constructed using the methods described herein, after annealing has been performed. In this example, the device is a double-side poly-Si (polycrystalline Si) passivated contact solar cell, meaning its first silicon layer 210 is positioned between two annealed silicon layers (250A and 250B) and two dielectric layers (200A and 200B). Here holes were formed on both sides of the double-side device, using the methods described herein. The first silicon layer 210 was n-doped, textured (pyramidal) silicon manufactured by the Czochralski process. The first silicon layer 210 was positioned between a first dielectric layer 200A and a second dielectric layer 200B, 200A constructed of SiOₓ and 200B constructed of a SiOₓ/SiNₓ stack, with the SiOₓ layer positioned between the SiNₓ layer and the first silicon layer 210. A SAM of HMDS (220A and 220B) was positioned on each dielectric layer (200A and 200B) and, after etching was performed, amorphous silicon layers (240A and 240B) were deposited onto the etched surfaces and then annealed to form annealed semiconductor layers (250A and 250B) positioned on SAMs (220A and 220B). In this exemplary device 100, the “top” annealed semiconductor layer 250A was constructed of n-doped polycrystalline silicon and the “bottom” annealed semiconductor layer 250B was constructed of using a first portion of intrinsic polycrystalline silicon and a second portion of p-doped polycrystalline silicon. Finally, metal contacts (400A and 400B) were added to both sides of the device 100.

These initial results show that the methods described above can provide a number of advantages over incumbent technologies, including a cost effective, low temperature, lithography-free alternative methods that can form holes 235 in dielectric layers 200 with improved control over the hole size, density, and placement on the device. For example, the methods described herein have been used to synthesize devices having engineered holes in industrially relevant poly-Si/SiO₂ (annealed semiconductor layer 250/dielectric layer 200) and poly-Si/SiNₓ/SiO₂ contacts (annealed semiconductor layer 250/first dielectric layer 200A/second dielectric layer 200B. SAMs 220 (HMDS) were formed on the surfaces of dielectric surfaces 200 to create templates for producing holes 235 through the dielectric layers 200 to ultimately form poly-Si passivated contacts. Fundamentally, a surface of a dielectric layer 200 can provide anchoring molecules for SAM precursor molecules, where a leaving group component (e.g., NH₂, CH₃, H₂O, and/or OH of the precursor molecule enables the bonding of the desired SAM 220 to the anchoring molecule on the surface of the dielectric layer 200. Area coverage of a SAM 220 on a dielectric layer 200 can be complete or partial depending on the conditions used for the first depositing 110. A first depositing 110 may be accomplished at room temperature (e.g., between 15° C. and 35° C.) in a variety of ambient gases (e.g., air, nitrogen, and/or argon), which can result in wider ranges of processing conditions for the first depositing 110, by utilizing, for example, the ambient soak method described herein. A deposited SAM 220 can subsequently serve as an etch resistant hard mask for contacting 120 the SAM 220/dielectric layer 200 with an etchant 114. Importantly, the methods described herein do not require the removal of a SAM 220 in a separate processing step and can, instead, remain in the device stack (e.g., fourth device 142) without impeding carrier transport.

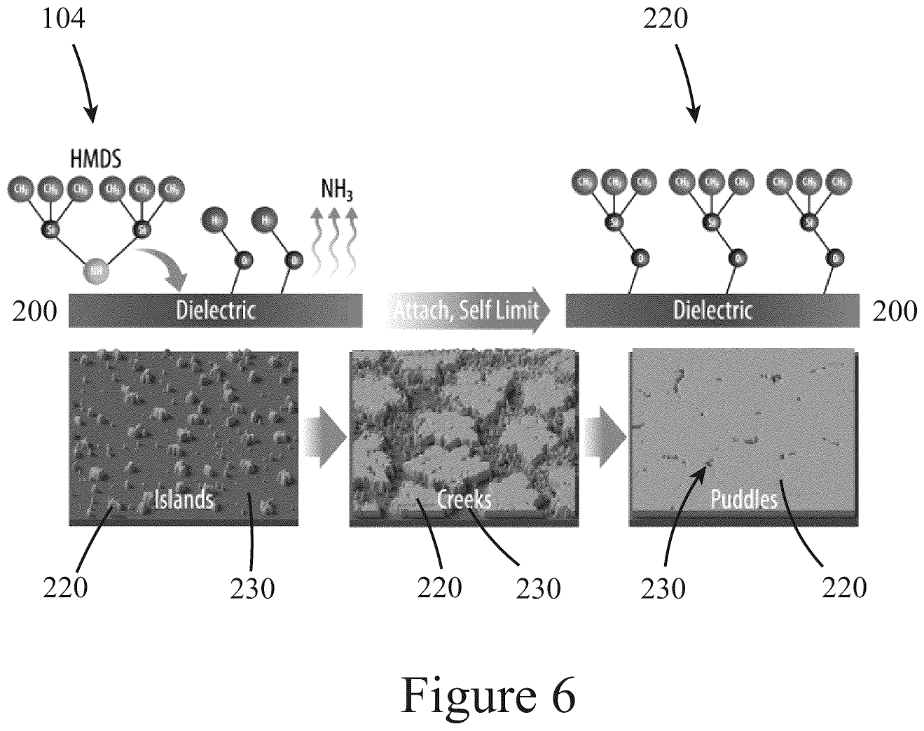

A SAM can be applied to various material surfaces to: 1) improve adhesion of subsequent layers/molecules; 2) increase chemical resistance to etching; and/or 3) tailor electronic transport when coupled with a metal or semiconductor. Thousands of SAM precursors exist for these and other functionalities. Hexamethyldisilazane (HMDS) is a SAM precursor that is used to form surface trimethyl-silyl groups via gas or liquid phase. The primary HMDS [(CH₃)₃Si]₂NH functionalization mechanism occurs when surface hydroxyl (—OH) anchoring groups react with the NH-leaving groups from the HMDS forming NH₃, and the Si(CH₃) 3 bonds to the remaining surface O-(see FIG. 6). FIG. 6 demonstrates that the percent coverage of a dielectric layer 200 by a SAM 220 can increase with time, approaching 100% coverage. Referring to the left panel of FIG. 6, a SAM 220 may only cover a small portion of the dielectric layer 200, forming small isolated “islands” of SAM. As time progresses, the percent coverage of the dielectric layer 200 by the SAM 220 may increase such that the original islands of SAMs merge together to form semi-continuous patches of SAM with intervening imperfections 230 having the appearance of creeks. Finally, with additional exposure of the dielectric surface 200 to the SAM precursor 104, the semi-continuous patches may merge together to form a continuous SAM 220 having only a few small, dispersed imperfections 230, as shown in the right-hand panel of FIG. 6.

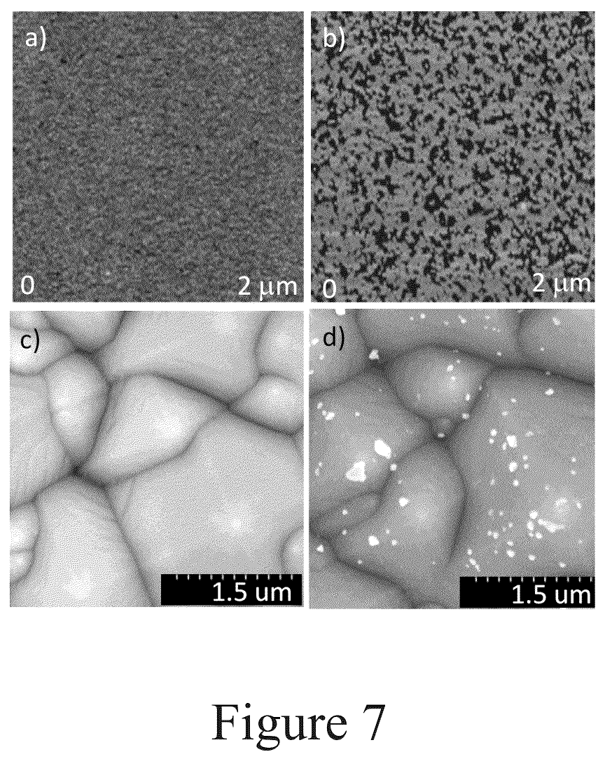

FIG. 7 illustrates AFM and SEM images of HMDS-derived SAM 220 covering a dielectric layer 200 positioned on a c-Si first silicon layer 210, Panel a) AFM pre-HF SiNₓ dielectric layer, Panel b) AFM post-HF SiNₓ dielectric layer, Panel c) SEM pre-HF SiO₂ dielectric layer, Panel d) SEM post-HF SiO₂ dielectric layer with Ag plating, according to some embodiments of the present disclosure. These results validate the mechanism illustrated in FIG. 6. AFM images show the transition from a smooth HMDS-derived SAM covered surface (see Panel a of FIG. 7), to HF etched holes with mild undercut (see Panel b of FIG. 7) increasing the area fraction of the exposed underlying c-Si second silicon layer. Additionally, an alternative method to visualize holes was implemented by soaking samples in a dilute AgNO₃ solution, where silver electrolessly plates onto the open holes where electrons are provided by the underlying first silicon layer, but not onto the surrounding dielectric layer. This can be seen in the SEM images (see Panel c of FIG. 7, pre-HF etch and Panel d of FIG. 7, post-HF etch) using a 2.0 nm thick SiO₂ dielectric layer positioned on a textured c-Si first silicon layer, where both samples were exposed to AgNO₃ simultaneously. In this example, the holes appear to be randomly distributed, and not specific to pyramid tips or valleys.

As previously described, SAM surface coverage of HMDS is temperature and time dependent. Surface coverage can be estimated by measuring the water contact angle (WCA) on a dielectric surface, with ˜100° indicating conformal coverage. Panel a of FIG. 8 shows the WCA on SiO₂ and SiNₓ dielectric layers as a function of HMDS room temperature vapor exposure. By the measure of WCA, full coverage was achieved in approximately 1000 minutes or in a range between 10 minutes and 100 minutes. Pretreating both SiO₂ and SiNₓ with a UV-O₃ exposure enhanced the SAMS coverage by oxidizing and removing surface contamination (hydrocarbons), which can block adhesion of the SAM-precursor molecules to the underlying dielectric layer. Further, the pretreatment of SiNₓ surfaces creates a thin surface oxide/oxynitride layer which is more susceptible to hydroxylation, enabling functionalization with HMDS.

Once SAMs were deposited over the dielectric layer, the resultant devices were contacted with an etchant of a 0.1% HF solution to etch the underlying dielectric layers through the imperfections present in the SAMs. To illustrate the effectiveness of HMDS-derived SAMs to act as an etch-stop layer, Panel b of FIG. 8 illustrates the thickness of an exemplary SiO₂ dielectric layer, as measured by ellipsometry, as a function of HF soak time for both a bare, SAM-free SiO₂ dielectric layer and a HMDS-derived SAM coated SiO₂ dielectric layer. Clearly, the SAM was relatively HF etch resistant as the bare SiO₂ dielectric layer was etched in approximately 25 minutes on a polished c-Si surface (i.e., a first silicon layer 210), while the HMDS covered sample remained intact 60 minutes for the same SiO₂ thickness. The minimum thicknesses shown in Panel b of FIG. 8 indicate where the samples became hydrophobic, and the fit to the data becomes more uncertain due to variations in surface roughness and other interfacial factors. Regardless, the SAM resulting from the application of HMDS to the SiO₂ dielectric layer extended the etch resistance of dielectric layer by at least 20 minutes. The etch rates are similar (the slope in Panel b of FIG. 8), so it may be hypothesized that the SAM had imperfections (e.g., holes, cracks, etc.) that allowed the HF etchant solution to etch the underlying SiO₂ dielectric layer, but eventually the undercutting of the etch removed the entire SAM layer. The etch resistant quality of the HMDS-derived SAM enables the methods described herein to selectively generate holes passing through the underlying dielectric layer of the uncovered regions of the SAM, regions having imperfections, while the SAM-covered surfaces of the dielectric layer remain intact. Thus, the imperfections present in a SAM may be utilized as a templating mask, effectively replacing the photoresist in a traditional lithography process.

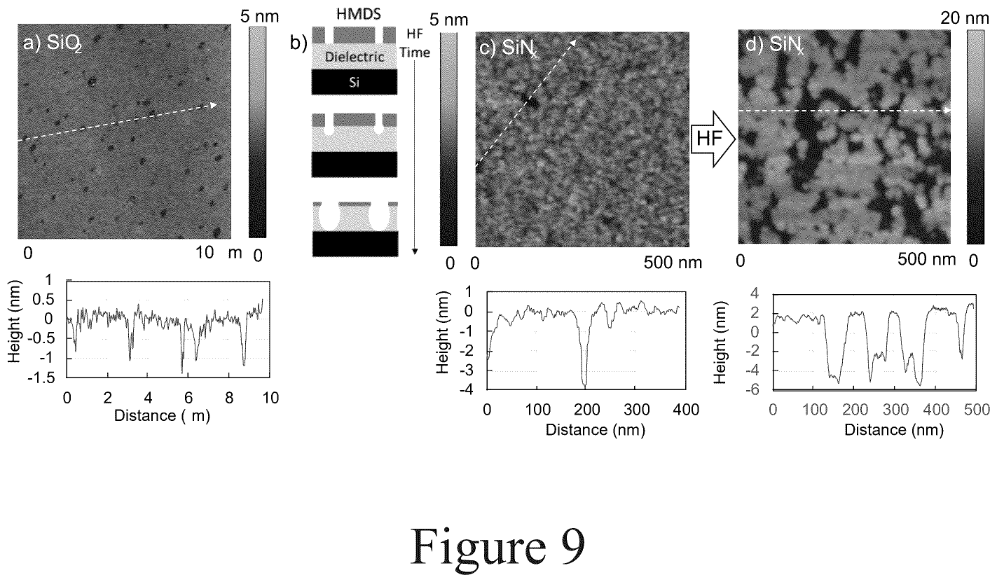

Dielectric Templating: Using the data from FIG. 8, a starting wafer 102 constructed of a c-Si first silicon layer 210 and a 2 nm thick SiO₂ dielectric layer 200 was exposed for about 90 minutes to HMDS vapor at room temperature (first depositing 110). This first depositing 110 resulted in incomplete SAM coverage (see Panel a of FIG. 8). The resultant first device 112 was then contacted (first contacting 120) by immersing it in a 0.1 vol % HF solution (i.e., etchant) for about 40 minutes, the amount of time needed to completely etch (i.e., generate holes that pass all the way through the dielectric layer) this SiO₂ (see Panel b of FIG. 8). Panel a of FIG. 9 shows an atomic force microscopy (AFM) image of the surface of the etched device 122, indicating the presence of holes 235 passing through the thickness of the dielectric layer 200, with hole 235 diameters between 100 nm and 1 um. Since the etching occurred in all directions, these features are likely larger than the diameters of imperfections present in the original SAM (see Panel b of FIG. 9). A similar test was completed on a thin 10 nm thick SiNₓ dielectric layer 200 positioned on a c-Si first silicon layer where the SiNₓ dielectric layer needed only 1 minute in a 0.1 vol % HF solution (i.e., etchant) to form holes passing through the entire thickness of the SiNₓ dielectric layer. Panel c of FIG. 9 shows an AFM image of a hole present in a SiNₓ dielectric layer resulting from a one of contacting with a 0.1 vol % HF solution, while Panel d of FIG. 9 shows a hole present in a SiNₓ dielectric layer resulting from three minutes contacting with a 0.1 vol % HF solution. Interestingly, intact SiNₓ surfaces were observed in the sample that was etched in HF for three minutes, which coincides with locations of the remaining HF resistant HMDS-derived SAM, indicating island-like SAM adhesion and possible undercutting and/or etching underneath the SAM layer.

Templated passivated contacts: Scanning Electron Microscopy (SEM) of holes present in SiO₂ dielectric layers: After creation of the templated SiO₂ dielectric layers 200 on first silicon layers 210 of c-Si, a second depositing 130 of a second silicon layer 240 constructed of doped a-Si:H was performed, followed by annealing 140 at a temperature of about 925° C. to convert the second semiconductor layer 240 of amorphous silicon layer 240 to a treated second semiconductor layer 250 of polycrystalline silicon. During the annealing 140, dopants diffused from the crystallizing poly-Si through the SiO₂, creating a shallow emitter, and through the holes 235 from the treated second semiconductor layer 250 (silicon) into the first silicon layer 210 of c-Si. Dopant diffusivity is much higher in polycrystalline silicon compared with SiO₂, so dopants selectively migrate to silicon-rich hole regions in the SiO₂ layer 242 which dopes not only the hole region, but also the region below the holes in the c-Si (first silicon layer 210).

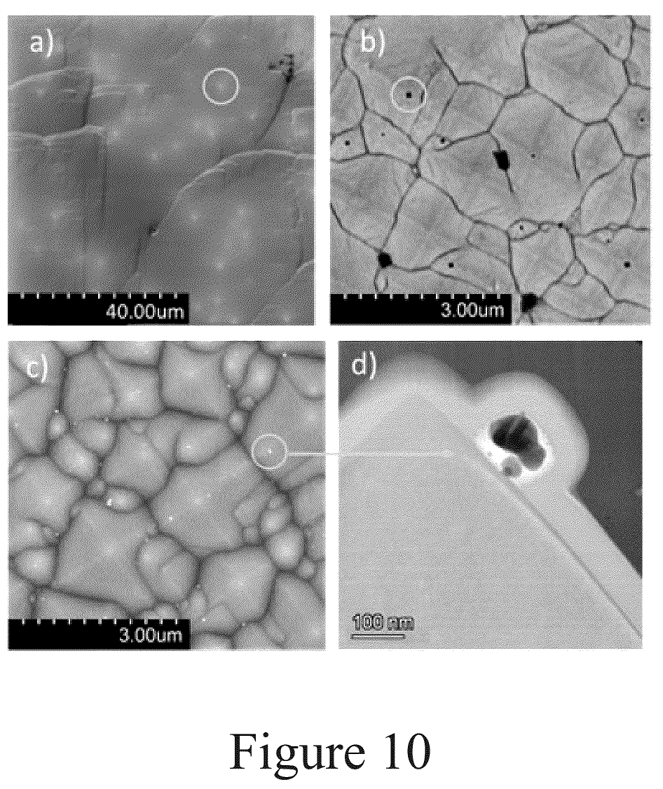

To visualize these holes 235/silicon penetrations 242, electron beam induced current (EBIC) measurements revealed brighter doped regions induced by the phosphorus diffusion from the second silicon layer 240 of n/poly-Si through the holes 235 and/or silicon penetrations 242) passing through the SiO₂ dielectric layer 200 into the first silicon layer 210 of c-Si (in this case having a saw damage etched morphology) to form a p-n junction (see Panel a of FIG. 10). These holes/penetrations do not appear to coincide with sharp surface morphological features. In contrast, after intentionally removing the n/poly-Si second silicon layer 240 from the random pyramid textured c-Si surface of the first silicon layer 210 with a tetramethylammonium hydroxide (TMAH) etch, where the SiO₂ dielectric layer 200 behaves as an etch stop, holes can be clearly seen at pyramid tips and valleys (see Panel b of FIG. 10). Lastly, an alternative method to visualize holes is via immersion in a dilute AgNO₃ solution (see Panel c of FIG. 10), where Ag plates onto the open holes (bright spots), but not onto the surrounding dielectric. Here, similar characteristics were observed, where holes are more prone to exist on sharp morphological features such as tips, ridges, and valleys (with examples circled in yellow) with the coinciding TEM image (see Panel d of FIG. 10) showing the cross section. SiO₂ thickness, intermediate-OH coverage on the SiO₂, and eventual HMDS coverage are all contributing factors to the presence, size, and areal density of hole formation. A protective SiNₓ layer was deposited on this sample after Ag precipitation to prevent damage/oxidation during TEM sample preparation.

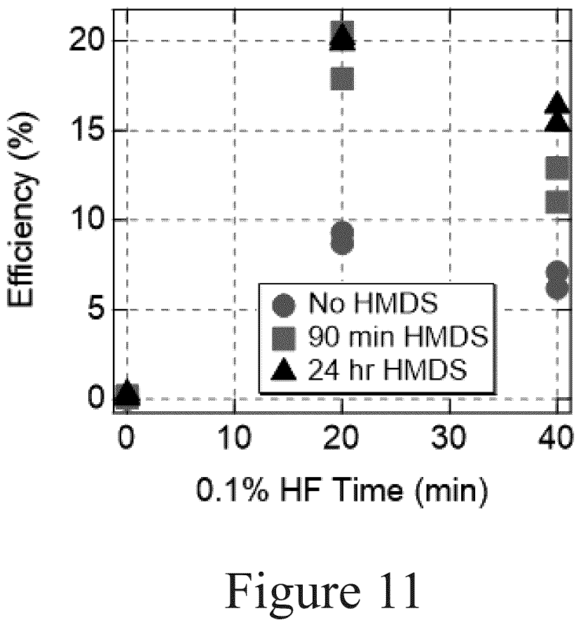

The interplay between incomplete HMDS surface functionalization, for the forming of a SAM 220, as well as the subsequent HF etch contacting time may be engineered to create holes to enable charge transport, while minimizing or eliminating recombination losses associated with the direct contact of a treated second semiconductor layer 250 (e.g., poly-Si layer) and a first silicon layer 210 (e.g., of crystalline silicon). The performance of a first generation of double side (DS-TXT) textured, templated SiO₂ passivated contact cells is illustrated in FIG. 11, where the efficiencies trend directly with cell V_{oc}. With no contacting 120 with an HF etchant 114, charge transport could not be attained through the SiO₂ dielectric layer 200, resulting in devices that essentially behaved like resistors.

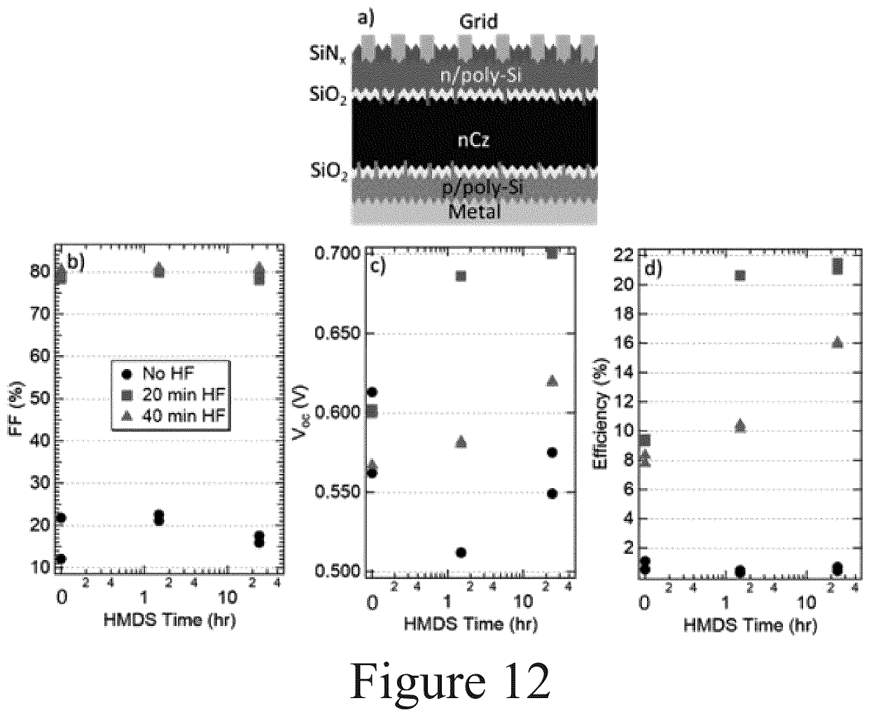

Both the incomplete HMDS surface functionalization as well as the subsequent HF etch time influence the resultant pinhole areal density. With too few pinholes in a dielectric interlayer, the contact resistivity increases and lowers the fill factor. Too many or too large pinholes increase the wafer contact area to heavily doped, defective poly-Si, lowering the open-circuit voltage (V_{oc}) due to Auger and Shockley-Read-Hall (SRH) recombination. A series of 4 cm² solar cells were prepared on double side textured (DS-TXT) n-Cz Si wafers with SAM-enabled passivated contacts on both sides (see Panel a of FIG. 12). Their performance parameters (fill-factor, open circuit voltage, efficiency) are illustrated in Panels b-d of FIG. 12 as a function of HMDS vapor soaking time. In this example, the device is double-sided with a first silicon layer 210 positioned between two dielectric layers 220. HMDS was then added to the dielectric surface, and the sample was etched with 0.1% HF. The resulting holes through the dielectric was enhanced by soaking the sample in AgNO₃/DI H₂O solution to nucleate the Ag particle on the exposed underlying conductive silicon wafer.

As the SiO₂ dielectric layer was etched without HMDS-derived SAM 220 (black circles), device behavior was poor (<10% efficiency), presumably due to uncontrolled conformal etching leading to increased c-Si surface recombination in the final device, resulting in a large area fraction defective poly-Si/c-Si interface and as well as excess surface doping. The addition of an HMDS-derived SAM 220 to the surface of SiO₂ dielectric layer and subsequent HF etching clearly resulted in desirable solar cell behavior, where an intermediate etch time of 20 minutes preserved the passivation (V_{oc}) resulting in >20% efficient cells. Table 1 shows device metrics, where the methods described herein were applied to both sides of a double-sided textured device using two dielectric layers, a 10 nm thick SiNₓ positioned on 1.2 nm thick SiOₓ layer (see Panel a of FIG. 12). After a first depositing of an HMDS-derived SAM, and contacting with HF solution, and depositing and annealing of a second silicon layer, the devices having the SiNₓ dielectric layer (with an underlying SiOₓ layer) achieved similar V_{oc} as the templated SiO₂ devices (˜690 mV) (e.g., devices having only one dielectric layer of SiO₂). However, the optics and hole densities still required improvements as demonstrated by the low J_{sc} and FF values. These methods were also applied to a cell that included a double-sided textured (DS-TXT) cells having layer stack of thermal SiO₂ and SiNₓ. This resulted in an approximately 10 mV increase in V_{oc} relative to the dielectric stack constructed using a 10 nm thick SiNₓ positioned on SiOₓ layer. In addition, by extending this approach to single side textured (SS-TXT) cells, where the p/poly-Si resided on the planarized rear side of the cell, the V_{oc} drastically increased to 723 mV.

TABLE 1
J-V characteristics of HMDS templated cells.

| | Dielectric | Tₐₙₙₑₐₗ | V_{oc} | J_{sc} | FF | η |
|---|---|---|---|---|---|---|
| Morphology | Interlayer | (° C.) | (V) | (mA/cm²) | (%) | (%) |
| DS-TXT | 10 nm SiNₓ | 850 | 0.692 | 36.4 | 74.0 | 18.7 |
| DS-TXT | 2 nm SiO₂ | 850 | 0.691 | 38.0 | 77.9 | 20.5 |
| DS-TXT | 2 nm SiO₂ | 925 | 0.686 | 37.7 | 79.8 | 20.6 |
| DS-TXT | 2 nm SiO₂ + 10 | 925 | 0.698 | 37.5 | 77.9 | 20.4 |
| | nm SiNₓ | | | | | |
| SS-TXT | 2 nm SiO₂ + 10 | 925 | 0.723 | 38.0 | 80.3 | 22.1 |
| | nm SiNₓ | | | | | |

### Experimental

In some embodiments, silicon wafers 102 were KOH texture etched, cleaned in standard clean (SC-1 and SC-2 solutions), and then oxidized in a tube furnace at 800° C. to form a thick, non-tunneling (˜2.0 nm) SiO₂ dielectric layer (200 dielectric layer). HMDS (Gelest, Inc.) was then applied via vapor exposure in a closed vessel for various durations at room temperature and pressure forming a SAM 220 partially covering the SiO₂ dielectric layer 200. Samples were then dipped in dilute 0.1% HF:DI H₂O for various times to etch the SiO₂ only through the openings (i.e., imperfections) in the HMDS layer due to its incomplete coverage. Without removing the HMDS layer, intrinsic and doped a-Si:H layers (i.e., second semiconductor layers 240) were then deposited onto the samples via 13.56 MHz RF plasma enhanced chemical vapor deposition (PECVD) using SiH₄, H₂, PH₃, and B₂H₆ at 1 Torr.

The resulting structures were then annealed in a tube furnace at 850° C. to crystallize and dope the second semiconductor layer 240, thereby forming the annealed semiconductor layer 250. Samples were coated with ALD deposited Al₂O₃ to provide a hydrogen-supplying layer to passivate the SiO₂/Si wafer interface, annealed at 400° C. for hydrogenation of that interface, and 2% HF dipped for subsequent metallization. The minority carrier lifetimes of the samples were measured using a Sinton WCT-120 lifetime tester prior to metallization. Water contact angle (WCA) measurements were taken using a Kruss drop shape analyzer. Thickness measurements were taken with an ellipsometer. Device J-V characteristics were measured under AM1.5G. Atomic force microscopy (AFM) images were taken using Veeco Dimension 5000 AFM and Nanoscope V controller. Each image had 256×256 pixels and was taken by tapping mode. A sharp silicon probe with tip radius of 7 nm and tip height of 14 mm (Olympus AC160TSA-R3) was used. Electron beam induced current (EBIC) measurements were performed on a JEOL JSM 7600 FESEM operated with an accelerating voltage of 5 kV and beam current of 1.3 nA. Quantitative current maps were acquired with a Mighty EBIC system from Ephemeron Labs.

### Device Examples

Example 1. A device comprising: a silicon layer; a dielectric layer having a thickness measured in a direction relative to a reference axis (y-axis); a self-assembled monolayer (SAM) having a thickness measured relative to the reference axis; and a layer comprising a semiconductor, wherein: the dielectric layer is positioned between the SAM and the silicon layer, the SAM is positioned between the layer comprising the semiconductor and the silicon layer, the SAM comprises a plurality of imperfections that pass through the thickness of the SAM, the dielectric layer comprises a plurality of holes that pass through at least a portion of the thickness of the dielectric layer, the imperfections and the holes are substantially aligned to form a plurality of continuous channels, at least a portion of the channels are at least partially filled with the semiconductor, and the channels are capable of charge transport between the silicon layer and the layer comprising the semiconductor.

Example 2. The device of Example 1, wherein the silicon layer is crystalline or amorphous.

Example 3. The device of either Example 1 or Example 2, wherein the silicon layer is n-doped or p-doped

Example 4. The device of any one of Examples 1-3, wherein the silicon layer has a textured surface.

Example 5. The device of any one of Examples 1-4, wherein the textured surface is at least one of corrugated, ridged, or grooved.

Example 6. The device of any one of Examples 1-5, wherein the textured surface comprises a plurality of pyramid-shaped structures.

Example 7. The device of any one of Examples 1-6, wherein the pyramid-shaped structures comprise a sharp surface comprising at least one of a tip, a ridge, a valley, or a combination thereof.

Example 8. The device of any one of Examples 1-7, wherein at least a portion of the holes are aligned relative to the y-axis with at least one of a sharp surface of the pyramid-shaped structures.

Example 9. The device of any one of Examples 1-8, wherein the imperfections comprise at least one of a hole, a crack, an area not covered by the SAM, or a combination thereof.

Example 10. The device of any one of Examples 1-9, wherein the SAM comprises a plurality of molecules.

Example 11. The device of any one of Examples 1-10, wherein the molecules comprise polyethylenimine (PEI).

Example 12. The device of any one of Examples 1-11, wherein each molecule comprises silicon.

Example 13. The device of any one of Examples 1-12, wherein the molecule comprises

at least one of hexamethyldisilazane (HMDS), trichlorooctadecylsilane, ((3-aminopropyl)triethoxysilane) (APTES), dimethylaminotrimethylsilane, N-methyl-aza-2,2,4-trimethylsilacyclopentane, a cyclic azosilanes, fluoro-alkyl silanes, or a combination thereof.

Example 14. The device of any one of Examples 1-13, wherein the dielectric layer comprises at least one of a metal oxide, a metal carbide, a metal nitride, or a combination thereof.

Example 15. The device of any one of Examples 1-14, wherein the metal of the metal oxide comprises at least one of silicon, aluminum, hafnium, tin, zirconium, titanium, zinc, or a combination thereof.

Example 16. The device of any one of Examples 1-15, The device of claim 1, wherein the dielectric layer comprises at least one of SiO_{z}, SiₓN_{y}, or a combination thereof, wherein 0.1≤z≤2.5, 0≤x≤2, and 0≤y≤2.

Example 17. The device of any one of Examples 1-16, wherein the dielectric layer has a textured surface that is like or approximates the textured surface of the silicon layer, including at least one of polished, pyramidal, or non-pyramidal.

Example 18. The device of any one of Examples 1-17, wherein the dielectric layer has a thickness between 0.1 nm and 200 nm.

Example 19. The device of any one of Examples 1-18, wherein a first portion of the plurality of holes terminate with a layer of the dielectric layer remaining in contact with the silicon layer.

Example 20. The device of any one of Examples 1-19, wherein the layer of the dielectric layer remaining has a thickness between 0.8 nm and 2.0 nm, or between 1.1 nm and 1.5 nm, or between 1.3 nm and 1.5 nm.

Example 21. The device of any one of Examples 1-20, wherein a first portion of the plurality of holes penetrate the entire thickness of the dielectric layer.

Example 22. The device of any one of Examples 1-21, wherein a second portion of the plurality of holes penetrate into the silicon layer.

Example 23. The device of any one of Examples 1-22, wherein the plurality of holes has an average diameter between 1 nm and 1000 nm.

Example 24. The device of any one of Examples 1-23, wherein the plurality of channels are present at a concentration between 1×10⁴ holes/cm² and 1×10¹⁰ holes/cm².

Example 25. The device of any one of Examples 1-24, wherein the semiconductor layer comprises at least one of silicon, titanium oxide, zinc oxide, tin oxide, indium oxide, indium-tin oxide, germanium, arsenic, antimony, aluminum, titanium, indium, molybdenum oxide, carbon, 2,2′,7,7′-tetrakis[N,N-di(4-methoxyphenyl)amino]-9,9′-spirobifluorene (spiro-OMeTAD), polymer poly[bis(4-phenyl)(2,4,6-trimethylphenyl)amine] (PTAA), CdTe, GaAs, AlSb, ZnTe, CdSe, or a combination thereof.

Example 26. The device of any one of Examples 1-25, wherein the semiconductor layer comprises crystalline silicon.

Example 27. The device of any one of Examples 1-26, wherein the crystalline silicon is polycrystalline silicon.

### Method Examples

Example 1. A method comprising: a first depositing of a self-assembled monolayer (SAM) onto a dielectric layer; and contacting the SAM with an etchant, wherein: the dielectric layer is a conformal layer covering a first silicon layer, after the first depositing, the SAM includes a first portion that prevents the dielectric layer from being contacted by the etchant and a second portion that allows the dielectric layer to be contacted by the etchant, and during the contacting, the etchant removes at least a portion of the dielectric layer underlying the second portion, resulting in the forming of a plurality of holes that penetrate into the dielectric layer.

Example 2. The method of Example 1, wherein the first depositing is performed by at least one of a vapor deposition method or a liquid deposition method.

Example 3. The method of either Example 1 or Example 2, wherein the vapor deposition method is performed for a period of time between 1 minute and 24 hours or between 1 minute and 16 hours or between 10 minutes and 100 minutes.

Example 4. The method of any one of Examples 1-3, wherein the etchant comprises a solution of at least one of hydrofluoric acid (HF), HNH₄F, or a combination thereof.

Example 5. The method of any one of Examples 1-4, wherein the HF is present in the solution at a concentration between 0.01 wt % and 5 wt % or between 0.1 wt % and 2 wt %.

Example 6. The method of any one of Examples 1-5, wherein the contacting is performed at a temperature between 20° C. and 100° C.

Example 7. The method of any one of Examples 1-6, wherein the contacting is performed for a period of time between 1 second and 60 minutes.

Example 8. The method of any one of Examples 1-7, wherein the contacting results in the SAM and the dielectric layer having a surface with a surface roughness between 0.1 nanometers and 20 nanometers.

Example 9. The method of any one of Examples 1-8, further comprising, after the contacting, a second depositing of a second semiconductor layer onto the SAM.

Example 10. The method of any one of Examples 1-9, further comprising, after the depositing of the amorphous silicon layer, annealing the amorphous silicon layer, wherein the annealing converts the amorphous silicon layer to a polycrystalline silicon layer.

Example 11. The method of any one of Examples 1-10, wherein the annealing is performed at a temperature between 600° C. and 1000° C.

Example 12. The method of any one of Examples 1-11, wherein the annealing results in the transfer of a dopant from polycrystalline silicon layer, through the plurality of holes, to the underlying crystalline silicon layer.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A device comprising:
a silicon layer;
a dielectric layer having a thickness;
a self-assembled monolayer (SAM) having a thickness; and
a layer comprising a semiconductor, wherein:
the dielectric layer is positioned between the SAM and the silicon layer,
the SAM is positioned between the layer comprising the semiconductor and the silicon layer,
the SAM comprises a plurality of imperfections that pass through the thickness of the SAM,
the dielectric layer comprises a plurality of holes that pass through at least a portion of the thickness of the dielectric layer,
the imperfections and the holes are substantially aligned to form a plurality of continuous channels,
at least a portion of the channels are at least partially filled with the semiconductor, and
the channels are capable of charge transport between the silicon layer and the layer comprising the semiconductor.

2. The device of claim 1, wherein the imperfections comprise at least one of a hole, a crack, an area not covered by the SAM, or a combination thereof.

3. The device of claim 1, wherein the SAM is derived from a plurality of SAM precursors molecules.

4. The device of claim 3, wherein the molecules comprise polyethylenimine (PEI).

5. The device of claim 3, wherein each molecule comprises silicon.

6. The device of claim 5, wherein the molecule comprises at least one of hexamethyldisilazane (HMDS), trichlorooctadecylsilane, ((3-aminopropyl)triethoxysilane) (APTES), dimethylaminotrimethylsilane, N-methyl-aza-2,2,4-trimethylsilacyclopentane, a cyclic azosilanes, fluoro-alkyl silanes, or a combination thereof.

7. The device of claim 1, wherein the dielectric layer comprises at least one of a metal oxide, a metal carbide, a metal nitride, or a combination thereof.

8. The device of claim 7, wherein the metal of the metal oxide comprises at least one of silicon, aluminum, hafnium, tin, zirconium, titanium, zinc, or a combination thereof.

9. The device of claim 1, wherein the dielectric layer comprises at least one of SiO_{z}, SiₓN_{y}, or a combination thereof, wherein 0.1≤z≤2.5, 0≤x≤2, and 0≤y≤2.

10. The device of claim 1, wherein the dielectric layer has a thickness between 0.1 nm and 200 nm.

11. The device of claim 1, wherein a first portion of the plurality of holes terminate with a layer of the dielectric layer remaining in contact with the silicon layer.

12. The device of claim 10, wherein the layer of the dielectric layer remaining has a thickness between 0.8 nm and 2.0 nm, or between 1.1 nm and 1.5 nm, or between 1.3 nm and 1.5 nm.

13. The device of claim 1, wherein a first portion of the plurality of holes penetrate the entire thickness of the dielectric layer.

14. The device of claim 13, wherein a second portion of the plurality of holes penetrate into the silicon layer.

15. The device of claim 1, wherein the plurality of holes has an average diameter between 1 nm and 1000 nm.

16. The device of claim 1, wherein the plurality of channels is present at a concentration between 1×10⁴ holes/cm² and 1×10¹⁰ holes/cm².

17. The device of claim 1, wherein the semiconductor layer comprises at least one of silicon, titanium oxide, zinc oxide, tin oxide, indium oxide, indium-tin oxide, germanium, arsenic, antimony, aluminum, titanium, indium, molybdenum oxide, carbon, 2,2′,7,7′-tetrakis[N,N-di(4-methoxyphenyl)amino]-9,9′-spirobifluorene (spiro-OMeTAD), polymer poly[bis(4-phenyl)(2,4,6-trimethylphenyl)amine] (PTAA), CdTe, GaAs, AlSb, ZnTe, CdSe, or a combination thereof.

18. The device of claim 1, wherein the semiconductor layer comprises crystalline silicon.

19. The device of claim 18, wherein the crystalline silicon is polycrystalline silicon.

20. A method comprising:
a first depositing of a self-assembled monolayer (SAM) onto a dielectric layer; and
contacting the SAM with an etchant, wherein:
the dielectric layer is a conformal layer covering a first silicon layer,
after the first depositing, the SAM includes a first portion that prevents the dielectric layer from being contacted by the etchant and a second portion that allows the dielectric layer to be contacted by the etchant, and
during the contacting, the etchant removes at least a portion of the dielectric layer underlying the second portion, resulting in the forming of a plurality of holes that penetrate into the dielectric layer.
